(19) United States
(12) Patent Application Publication
(10) Pub. No.: US 2025/0393448 A1
(43) Pub. Date: Dec. 25, 2025

(54) DISPLAY DEVICE, AND ELECTRONIC DEVICE INCLUDING THE SAME

(71) Applicant: Samsung Display Co., LTD., Yongin-si (KR)

(72) Inventors: Hyunho JUNG, Yongin-si (KR); Hyungue SONG, Yongin-si (KR); Heeseong JEONG, Yongin-si (KR); Sangmin HONG, Yongin-si (KR)

(21) Appl. No.: 19/243,195

(22) Filed: Jun. 19, 2025

(30) Foreign Application Priority Data
Jun. 20, 2024 (KR) 10-2024-0080586

(51) Int. Cl. H10K 59/80

(52) U.S. Cl. CPC H10K 59/879; H10K 59/873

(57) ABSTRACT

A display device includes a substrate, a first organic light-emitting diode disposed on the substrate, a first capping layer disposed on the first organic light-emitting diode and having a first refractive index, a second capping layer disposed on the first capping layer and having a second refractive index less than the first refractive index, and a first-1 inorganic encapsulation layer disposed on the second capping layer and having a third refractive index greater than the second refractive index.

This application claims priority to Korean Patent Application No. 10-2024-0080586, filed on Jun. 20, 2024, and all the benefits accruing therefrom under 35 U.S.C. § 119, the content of which in its entirety is herein incorporated by reference.

### BACKGROUND

### 1. Field

One or more embodiments relate to a display device.

### 2. Description of the Related Art

Display devices visually display data. The display devices may provide images using light-emitting diodes. The usage of the display devices is becoming versatile, and various designs are attempted to improve the quality of the display devices.

### SUMMARY

One or more embodiments include a display device.

Additional aspects will be set forth in part in the description which follows and, in part, will be apparent from the description, or may be learned by practice of the presented embodiments of the disclosure.

According to one or more embodiments, a display device includes a substrate, a first organic light-emitting diode disposed on the substrate, a first capping layer disposed on the first organic light-emitting diode and having a first refractive index, a second capping layer disposed on the first capping layer and having a second refractive index less than the first refractive index, and a first-1 inorganic encapsulation layer disposed on the second capping layer and having a third refractive index greater than the second refractive index.

According to one or more embodiments, the third refractive index of the first-1 inorganic encapsulation layer may be about 1.79 to about 1.99.

According to one or more embodiments, a thickness of the first capping layer may be about 100 angstroms (Å) to about 2,000 Å.

According to one or more embodiments, a thickness of the second capping layer may be about 100 Å to about 2,000 Å.

According to one or more embodiments, a thickness of the first-1 inorganic encapsulation layer may be about 1,000 Å to about 30,000 Å.

According to one or more embodiments, the display device may further include a first-2 inorganic encapsulation layer disposed on the first-1 inorganic encapsulation layer and having a fourth refractive index less than the third refractive index.

According to one or more embodiments, the fourth refractive index of the first-2 inorganic encapsulation layer may be about 1.6 to about 1.8.

According to one or more embodiments, a thickness of the first-2 inorganic encapsulation layer may be about 300 Å to about 1,500 Å.

According to one or more embodiments, the first-2 inorganic encapsulation layer may include a lower layer and an upper layer, a refractive index of the lower layer may be about 1.67 to about 1.87, and a refractive index of the upper layer may be about 1.52 to about 1.72.

According to one or more embodiments, a thickness of each of the lower layer and the upper layer may be about 300 Å to about 1,500 Å.

According to one or more embodiments, the display device may further include a first-3 inorganic encapsulation layer disposed on the first-2 inorganic encapsulation layer and having a fifth refractive index less than the fourth refractive index.

According to one or more embodiments, the display device may further include a third capping layer disposed under the first capping layer and having a sixth refractive index less than the second refractive index.

According to one or more embodiments, the display device a thickness of the third capping layer may be about 100 Å to about 2,000 Å.

According to one or more embodiments, an electronic device includes a display device and a power supply configured to provide power to the display device. The display device includes a substrate, a first organic light-emitting diode, a second organic light-emitting diode, and a third organic light-emitting diode disposed on the substrate, a first-1 capping layer disposed on the first organic light-emitting diode, a first-2 capping layer disposed on the second organic light-emitting diode, a first-3 capping layer disposed on the third organic light-emitting diode, a second-1 capping layer disposed on the first-1 capping layer and having a refractive index less than a refractive index of the first-1 capping layer, a second-2 capping layer disposed on the first-2 capping layer and having a refractive index less than a refractive index of the first-2 capping layer, and a second-3 capping layer disposed on the first-3 capping layer and having a refractive index less than a refractive index of the first-3 capping layer, where a thickness of the first-1 capping layer and a thickness of the first-3 capping layer are different from each other.

According to one or more embodiments, the first organic light-emitting diode, the second organic light-emitting diode, and the third organic light-emitting diode may emit light of different colors from each other.

According to one or more embodiments, a thickness of the second-1 capping layer and a thickness of the second-3 capping layer may be different from each other.

According to one or more embodiments, a thickness of each of the first-1 capping layer, the first-2 capping layer, the first-3 capping layer, the second-1 capping layer, the second-2 capping layer, and the second-3 capping layer may be about 100 Å to about 2,000 Å.

According to one or more embodiments, the electronic device may further include a first-1 inorganic encapsulation layer disposed on the second-1 capping layer, the second-2 capping layer, and the second-3 capping layer and having a refractive index greater than a refractive index of each of the second-1 capping layer, the second-2 capping layer, and the second-3 capping layer.

According to one or more embodiments, a refractive index of the first-1 inorganic encapsulation layer may be about 1.79 to about 1.99.

According to one or more embodiments, a thickness of the first-1 inorganic encapsulation layer may be about 1,000 Å to about 30,000 Å.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 schematically shows a perspective view of a display device according to an embodiment;

FIG. 2 schematically shows an equivalent circuit diagram of a subpixel circuit included in a display device according to an embodiment;

FIG. 3 schematically shows a cross-sectional view of a display device;

FIGS. 4 to 7 are schematic cross-sectional views of a portion of a display panel according to some embodiments;

FIGS. 8 to 10 schematically show results of a simulation of light emission rate and WAD trajectory, according to an embodiment; And

FIG. 11 is a block diagram illustrating an electronic device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b, or c” indicates only a, only b, only c, both a and b, both a and c, both b and c, all of a, b, and c, or variations thereof.

Because the disclosure may have diverse modified embodiments, embodiments are illustrated in the drawings and are described in the detailed description. An effect and a characteristic of the disclosure, and a method of accomplishing these will be apparent when referring to embodiments described with reference to the drawings. The disclosure may, however, be embodied in many different forms and should not be construed as limited to the embodiments set forth herein.

One or more embodiments will be described below in more detail with reference to the accompanying drawings. Those elements that are the same or are in correspondence are rendered the same reference numeral regardless of the figure number, and redundant descriptions thereof are omitted.

It will be understood that although terms such as “first”, “second”, “first-1”, “first-2”, “second-1”, “second-2”, etc. may be used herein to describe various elements, these elements should not be limited by these terms and these terms are only used to distinguish one element from another element.

As used herein, the singular forms “a,” “an,” and “the” are intended to include the plural forms as well, unless the context clearly indicates otherwise.

Also, it will be understood that the terms “comprise,” “include,” and “have” used herein specify the presence of stated features or elements, but do not preclude the presence or addition of one or more other features or elements.

It will be understood that when a layer, region, or element is referred to as being “on” another layer, region, or element, it may be “directly on” the other layer, region, or element or may be “indirectly on” the other layer, region, or element with one or more intervening layers, regions, or elements therebetween.

In the drawings, for convenience of description, sizes of components may be exaggerated or reduced. In other words, since sizes and thicknesses of elements in the drawings are arbitrarily illustrated for convenience of description, the following embodiments are not limited thereto.

When a certain embodiment may be implemented differently, a specific process order may be performed differently from the described order. For example, two consecutively described processes may be performed substantially at the same time or performed in an order opposite to the described order.

“About” or “substantially the same” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±10%, 5% or 2% of the stated value.

In the embodiments hereinafter, it will be understood that when an element, an area, or a layer is referred to as being connected to another element, area, or layer, it can be directly and/or indirectly connected to the other element, area, or layer. For example, in the specification, when a layer, region, component, or the like is electrically connected to another layer, region, component, or the like, the layer, region, component, or the like may be directly electrically connected thereto and/or may be indirectly electrically connected thereto with an intervening layer, region, component, or the like therebetween.

In the following examples, the x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

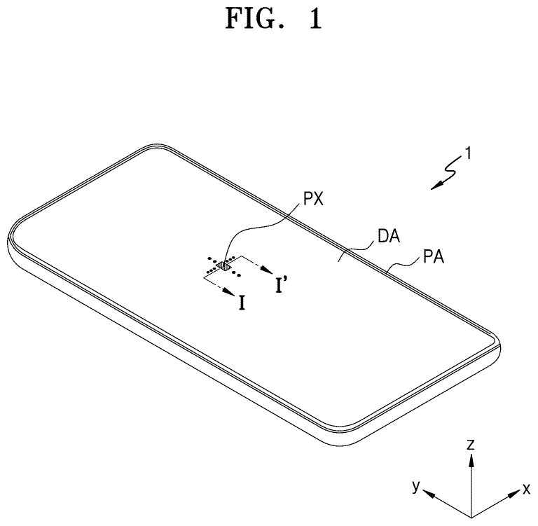

FIG. 1 schematically shows a perspective view of a display device according to an embodiment.

The display device according to embodiments may display a moving image or a still image, and may be used as displays of various electronic devices such as portable electronic devices such as a mobile phone, a smart phone, a tablet personal computer (“PC”), a mobile communication device, an electronic notepad, an electronic book, a portable multimedia player (“PMP”), a navigation device, and an ultramobile PC (“UMPC”), and a television, a notebook computer, a monitor, a billboard, and internet of things (“IOT”). Furthermore, the display device according to an embodiment may be used in a wearable device, such as a smart watch, a watch phone, an eyewear display, and a head mounted display (“HMD”). In addition, the display device according to an embodiment may be used as a dashboard of a vehicle, a center information display (“CID”) arranged in a center fascia or dashboard of a vehicle, a room mirror display replacing the side mirror of a vehicle, an entertainment for the back seat of a vehicle, and a display arranged on the rear surface of the front seat.

Referring to FIG. 1, the display device 1 may have edges each in a first direction and a second direction. The first direction and the second direction may cross each other. For example, the first direction and the second direction may form an acute angle. In another example, the first direction and the second direction may form an obtuse angle or a right angle. Hereinafter, descriptions will mainly be made regarding cases in which the first direction and the second direction are perpendicular to each other. For example, the first direction may be an x or −x direction, and the second direction may be a y or −y direction. A third direction perpendicular to the first and second directions may be a z or −z direction.

The display device 1 may include a display area DA and a peripheral area PA outside of the display region DA. The display device 1 may provide a certain image by using light emitted from a plurality of subpixels PX arranged in the display area DA. The peripheral area PA, which is disposed outside of the display area DA, may be a type of a non-display area in which subpixels are not arranged. The entire display area DA may be surrounded by the peripheral area PA.

Hereinafter, although an organic light-emitting display device is described as a display device according to an embodiment, the display device of the disclosure is not limited thereto. In another embodiment, the display device of the disclosure may be an inorganic light-emitting display or an inorganic EL display, or a quantum dot light-emitting display. For example, an emission layer of a display element included in the display device may include an organic material or an inorganic material. Furthermore, the display device may include an emission layer and quantum dots located on a path of light emitted from the emission layer.

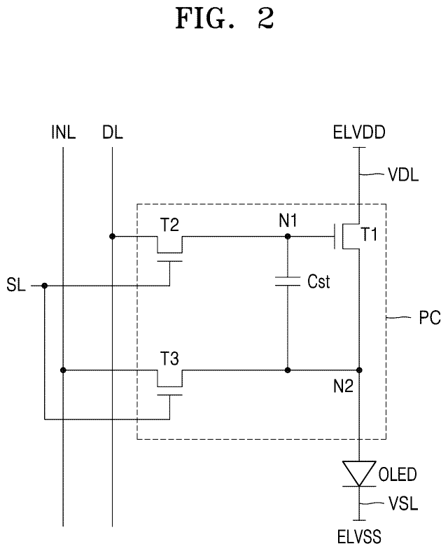

FIG. 2 schematically shows an equivalent circuit diagram of a subpixel circuit included in the display device according to an embodiment.

Referring to FIG. 2, the subpixel circuit PC may include a plurality of thin-film transistors and at least one capacitor. In an embodiment, the subpixel circuit PC may include a first thin-film transistor T1, a second thin-film transistor T2, a third thin-film transistor T3, and a storage capacitor Cst.

Each of the first thin-film transistor T1, the second thin-film transistor T2, and the third thin-film transistor T3 may be an oxide semiconductor thin-film transistor including a semiconductor layer including an oxide semiconductor, or a silicon semiconductor thin-film transistor including a semiconductor layer including polysilicon. Each thin-film transistor may include a first electrode and a second electrode, the first electrode may be one of a source electrode and a drain electrode according to the type of the thin-film transistor, and the second electrode may be the other one of the source electrode and the drain electrode. In addition, each thin-film transistor may include a gate electrode.

The first thin-film transistor T1 may include a driving thin-film transistor. The first electrode of the first thin-film transistor T1 may be connected to a driving voltage line VDL configured to supply a driving power supply voltage ELVDD, and the second electrode of the first thin-film transistor T1 may be connected to a pixel electrode of the organic light-emitting diode OLED. The gate electrode of the first thin-film transistor T1 may be connected to a first node N1. The first thin-film transistor T1 may control the amount of current flowing to the organic light-emitting diode OLED from the driving power supply voltage ELVDD in response to a voltage of the first node N1.

The second thin-film transistor T2 may include a switching thin-film transistor. The first electrode of the second thin-film transistor T2 may be connected to the data line DL, and the second electrode of the second thin-film transistor T2 may be connected to the first node N1. The gate electrode of the second thin-film transistor T2 may be connected to a scan line SL. The second thin-film transistor T2 may may be turned on when a scan signal is supplied to the scan line SL, thereby electrically connecting the data line DL to the first node N1.

The third thin-film transistor T3 may include an initialization thin-film transistor and/or a sensing thin-film transistor. The first electrode of the third thin-film transistor T3 may be connected to a second node N2, and the second electrode of the third thin-film transistor T3 may be connected to an initialization voltage line INL. The gate electrode of the third thin-film transistor T3 may be connected to the scan line SL.

The third thin-film transistor T2 may be turned on when the scan signal is supplied to the scan line SL, thereby electrically connecting the initialization voltage line INL to the second node N2. In some embodiments, the third thin-film transistor T3 may be turned on according to a signal received through the scan line SL to initialize the pixel electrode of the organic light-emitting diode OLED through an initialization voltage from the initialization voltage line INL.

In some embodiments, the third thin-film transistor T3 may be turned on when the scan signal is supplied to the scan line SL and sense characteristic information of the organic light-emitting diode OLED. The third thin-film transistor T3 may include both an initialization thin-film transistor function and a sensing thin-film transistor function or may include one of the two functions. An initialization operation and a sensing operation of the third thin-film transistor T3 may be proceeded individually or at the same time. If the third thin-film transistor T3 includes the sensing thin-film transistor function, the initialization voltage line INL may be referred to as a sensing line.

The storage capacitor Cst may be connected between the first node N1 and the second node N2. For example, the first capacitor plate of the storage capacitor Cst may be connected to the gate electrode of the first thin-film transistor T1, and a second capacitor plate of the storage capacitor Cst may be connected to the pixel electrode of the organic light-emitting diode OLED.

An opposite electrode of the organic light-emitting diode OLED may be connected to a common voltage line VSL configured to provide a common power supply voltage ELVSS.

Although FIG. 2 illustrates that the subpixel circuit PC includes three thin-film transistors and one storage capacitor, the disclosure is not limited thereto. In some embodiments, the number of thin-film transistors or the number of storage capacitors may be variously modified according to the design of the subpixel circuit PC.

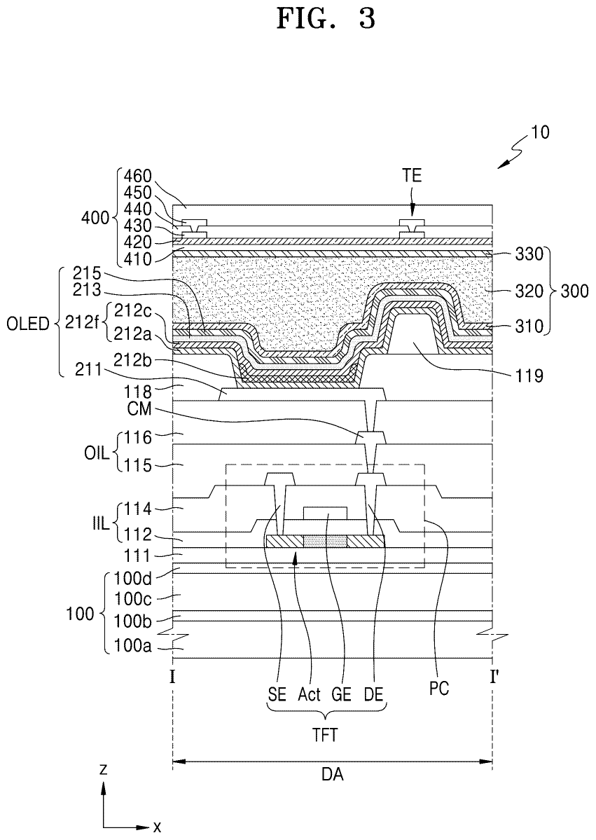

FIG. 3 schematically shows a cross-sectional view of the display device. Particularly, FIG. 3 shows a cross-sectional view of the display device of FIG. 1 taken along line I-I′.

Referring to FIG. 3, the display panel 10 may include a substrate 100, an inorganic insulating layer IIL, an organic insulating layer OIL, a subpixel circuit PC, a connection electrode CM, an organic light-emitting diode OLED, a third organic insulating layer 118, a spacer 119, and an encapsulation layer 300. That is, the substrate 100, the inorganic insulating layer IIL, the organic insulating layer OIL, the subpixel circuit PC, the connection electrode CM, the organic light-emitting diode OLED, the third organic insulating layer 118, the spacer 119, and the encapsulation layer 300 may be arranged on the display area DA of the display panel 10.

The substrate 100 may include a first base layer 100a, a first barrier layer 100b, a second base layer 100c, and a second barrier layer 100d. In an embodiment, the first base layer 100a, the first barrier layer 100b, the second base layer 100c, and the second barrier layer 100d may be sequentially stacked in the thickness direction (z direction) of the substrate 100.

At least one of the first base layer 100a and the second base layer 100c may include a polymer resin such as polyethersulfone, polyarylate, polyetherimide, polyethylene naphthalate, polyethylene terephthalate, polyphenylene sulfide, polyimide, polycarbonate, cellulose tri acetate, cellulose acetate propionate, etc.

The first barrier layer 100_{b} and the second barrier layer 100_{d} may prevent the penetration of external foreign substances and may have a single-layer or multi-layer structure including silicon nitride (SiNₓ), silicon oxide (SiO₂), and/or silicone oxynitride (SiON).

A buffer layer 111 may be disposed on the substrate 100. The buffer layer 111 may include inorganic insulating materials such as SiNₓ, SiON, and SiO₂ and may have a single-layer or multi-layer structure including the inorganic insulators described above.

The inorganic insulation layer IIL may be disposed on the buffer layer 111. The inorganic insulating layer IIL may include a first inorganic insulating layer 112 and a second inorganic insulating layer 114. However, the disclosure is not limited thereto.

A subpixel circuit PC may be arranged in the display area DA. The subpixel circuit PC may include a thin-film transistor TFT. The thin-film transistor TFT may include a semiconductor layer Act, a gate electrode GE, a source electrode SE, and a drain electrode DE.

The semiconductor layer ACT may be disposed on the buffer layer 111. The semiconductor layer Act may include polysilicon. Alternatively, the semiconductor layer Act may include amorphous silicon, an oxide semiconductor, or an organic semiconductor. The semiconductor layer Act may include a channel area and a drain area and a source area arranged on opposite sides of the channel area, respectively.

The gate electrode GE may be disposed on the semiconductor layer Act. The gate electrode GE may overlap the channel area. The gate electrode GE may include a low-resistance metal material. The gate electrode GE may include a conductive material including molybdenum (Mo), aluminum (Al), copper (Cu), titanium (Ti), etc. and may have a single-layer or multi-layer structure layer including the conductive materials described above.

The first inorganic insulating layer 112 may be arranged between the semiconductor layer Act and the gate electrode GE. The first inorganic insulating layer 112 may include an inorganic insulating material such as SiO₂, SiNₓ, SiON, aluminum oxide (Al₂O₃), titanium oxide (TiO₂), tantalum oxide (Ta₂O₅), hafnium oxide (HfO₂), or zinc oxide (ZnO).

The second inorganic insulating layer 114 may be disposed on the gate electrode GE. The second inorganic insulating layer 114 may cover the gate electrode GE. The second inorganic insulating layer 114 may include an inorganic insulating material such as SiO₂, SiNₓ, SiON, Al₂O₃, TiO₂, Ta₂O₅, HfO₂, or ZnO.

The drain electrode DE and the source electrode SE may each be disposed on the second inorganic insulating layer 114. The drain electrode DE and the source electrode SE may each be connected to the semiconductor layer Act through a contact hole defined in the first inorganic insulating layer 112 and the second inorganic insulating layer 114. The drain electrode DE and the source electrode SE may include materials with great conductivity. The drain electrode DE and the source electrode SE may include conductive materials including Mo, Al, Cu, Ti, etc. and have a single-layer or multi-layer structure including the materials described above. For example, the drain electrode DE and the source electrode SE may have a multi-layer structure of Ti/Al/Ti.

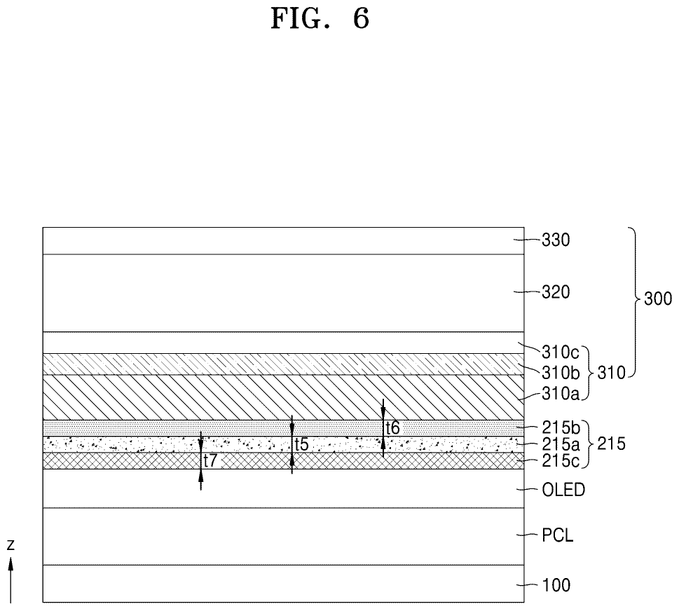

The organic insulating layer OIL may be disposed on the inorganic insulating layer IIL. The organic insulating layer OIL may include a first organic insulating layer 115 and a second organic insulating layer 116. FIG. 6 shows two organic insulating layers OIL provided, but the disclosure is not limited thereto. The number of organic insulating layers OIL may be three or four in another embodiment.

The first organic insulating layer 115 may cover the drain electrode DE and the source electrode SE. The first organic insulating layer 115 may include an organic insulating material, such as a general-purpose polymer, such as polymethylmethacrylate (“PMMA”) or polystyrene (“PS”), polymer derivatives having a phenol-based group, acryl-based polymers, imide-based polymers, arylether-based polymers, amide-based polymers, fluorine-based polymers, p-xylene-based polymers, vinyl alcohol-based polymers, and a blend thereof.

The connection electrode CM may be disposed on the first organic insulating layer 115. In this case, the connection electrode CM may be connected to the drain electrode DE or the source electrode SE through the contact hole of the first organic insulating layer 115. The connection electrode CM may include a material with good conduction. The connection electrode CM may include a conductive material including Mo, Al, Cu, Ti, etc. and may have a single-layer or multi-layer structure including the conductive materials described above. For example, the connection electrode CM may have a multi-layer structure of Ti/Al/Ti.

The second organic insulating layer 116 may be disposed on the connection electrode CM. The second organic insulating layer 116 may cover the connection electrode CM. The second organic insulating layer 116 may include a material that is identical to or different from the first organic insulating layer 115.

A light-emitting diode may be disposed on the second organic insulating layer 116. For example, an organic light-emitting diode OLED may be disposed on the second organic insulating layer 116. Alternatively, although not shown, an inorganic light-emitting diode may be disposed on the second organic insulating layer 116.

The organic light-emitting diode OLED may emit red, green, or blue light, or may emit red, green, blue, or white light. The organic light-emitting diode OLED may include a first electrode 211, an emission layer 212b, a functional layer 212f, a second electrode 213, and a capping layer 215. The first electrode 211 may be a pixel electrode (e.g., an anode) of the organic light-emitting diode OLED and the second electrode 213 may be an opposite electrode (e.g., a cathode) of the organic light-emitting diode OLED.

The first electrode 211 may be disposed on the second organic insulating layer 116. The first electrode 211 may be electrically connected to the connection electrode CM through the contact hole of the second organic insulating layer 116. The first electrode 211 may include a conductive oxide, such as indium tin oxide (“ITO”), indium zinc oxide (“IZO”), zinc oxide (ZnO), indium oxide (In₂O₃), indium gallium oxide (“IGO”), or aluminum zinc oxide (“AZO”). In an embodiment, the first electrode 211 may include a reflective layer including Ag, Mg, Al, Pt, Pd, Au, Ni, Nd, Ir, Cr, or a compound thereof. In an embodiment, the first electrode 211 may further include a layer including ITO, IZO, ZnO, or In₂O₃ above/below the reflective layer described above. For example, the first electrode 211 may have a multi-layer structure of an ITO/Ag/ITO.

The third organic insulating layer 118 defining an opening that exposes at least a portion of the first electrode 211 may be disposed on the first electrode 211. The emission area of light emitted from the organic light-emitting diode OLED may be defined by the opening defined in the third organic insulating layer 118. For example, the width of the opening may correspond to the width of the emission area.

The third organic insulating layer 118 may include an organic insulating material. The third organic insulating layer 118 may include an inorganic insulating material, such as SiNₓ, SiON, or SiO₂. Alternatively, the third organic insulating layer 118 may include an organic insulating material and an inorganic insulating material. In an embodiment, the third organic insulating layer 118 may include a light blocking material. The light blocking material may include a resin or paste including carbon black, carbon nanotube, or black dyes, metal particles such as Ni, Al, Mo, and an alloy thereof, metal oxide particles (for example, chrome oxide), or metal nitride particles (for example, chrome nitride). When the third organic insulating layer 118 includes a light blocking material, external light reflected by metal structures disposed under the third organic insulating layer 118 may be reduced.

The spacer 119 may be disposed on the third organic insulating layer 118. The spacer 119 may include an organic insulating material, such as polyimide. Alternatively, the spacer 119 may include an inorganic insulating material such as SiNₓ or SiO₂ or may include an organic insulating material and an inorganic insulating material.

In an embodiment, the spacer 119 may include the same material as the third organic insulating layer 118. In this case, the third organic insulating layer 118 and the spacer 119 may be formed together by a mask process using a halftone mask, etc. Alternatively, the spacer 119 and the third organic insulating layer 118 may include different materials.

The emission layer 212b may be disposed on the opening of the third organic insulating layer 118. The emission layer 212b may include a high molecular-weight or low molecular-weight organic material emitting a predetermined color of light.

The functional layer 212f may include a first functional layer 212a and a second functional layer 212c. The first functional layer 212a may be arranged between the first electrode 211 and the emission layer 212b, and the second functional layer 212c may be arranged between the emission layer 212b and the second electrode 213. However, at least one of the first functional layer 212a and the second functional layer 212c may be omitted. Hereinafter, cases where the first functional layer 212a and the second functional layer 212c are disposed will each be described in detail.

The first functional layer 212a may include a hole transport layer (“HTL”) and/or a hole injection layer (“HIL”). The second functional layer 212c may include an electron transport layer (“ETL”) and/or an electron injection layer (“EIL”). The first functional layer 212a and/or the second functional layer 212c may be a common layer formed to cover the entire substrate 100 in the same manner as the second electrode 213 described later.

The second electrode 213 may be disposed on the functional layer 212f. The second electrode 213 may include a conductive material having a low work function. For example, the second electrode 213 may include a (semi) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the second electrode 213 may further include a layer, such as ITO, IZO, ZnO, or In₂O₃, on the (semi) transparent layer including the material described above.

In an embodiment, a capping layer 215 may be disposed on the second electrode 213. The capping layer 215 may include lithium fluoride (LiF), an inorganic material, or/and an organic material.

The encapsulation layer 300 may be disposed on the organic light-emitting diode OLED. The encapsulation layer 300 may cover the organic light-emitting diode OLED. The encapsulation layer 300 may be disposed on the second electrode 213 and/or the capping layer 215. In an embodiment, the encapsulation layer 300 may include at least one inorganic encapsulation layer and at least one organic encapsulation layer. FIG. 3 shows that the encapsulation layer 300 includes a first inorganic encapsulation layer 310, an organic encapsulation layer 320, and a second inorganic encapsulation layer 330 that are sequentially stacked.

The encapsulation layer 300 may include the first inorganic encapsulation layer 310 and the second inorganic encapsulation layer 330. The first inorganic encapsulation layer 310 and the second inorganic encapsulation layer 330 may each include one or more inorganic materials from among aluminum oxide (Al₂O₃), titanium oxide (TiO), tantalum oxide (TA₂O₅), hafnium oxide (HfO₂), ZnO, SiOx, SiNx, and SiON. The first inorganic encapsulation layer 310 and the second inorganic encapsulation layer 330 may each be a single layer or layers including the material described above. The organic encapsulation layer 320 may include a polymer-based material. Examples of the polymer-based material may include an acrylic resin, an epoxy resin, polyimide, and polyethylene. In an embodiment, the organic encapsulation layer 320 may include acrylate.

An input detection layer 400 may be disposed on the encapsulation layer 300. The input detection layer 400 may include a first touch insulating layer 410, a second touch insulating layer 420, a first conductive layer 430, a third touch insulating layer 440, a second conductive layer 450, and a planarization layer 460. A touch insulating layer 40 may include the first touch insulating layer 410, the second touch insulating layer 420, and/or the third touch insulating layer 440.

In an embodiment, the first touch insulating layer 410 may be disposed on the second inorganic encapsulation layer 330, and the second touch insulating layer 420 may be disposed on the first touch insulating layer 410. In an embodiment, the first touch insulating layer 410 and the second touch insulating layer 420 may include an organic insulating material.

In an embodiment, at least one of the first touch insulating layer 410 and the second touch insulating layer 420 may be omitted. For example, the first touch insulating layer 410 may be omitted. In this case, the second touch insulating layer 420 may be disposed on the second inorganic encapsulation layer 330, and the first conductive layer 430 may be disposed on the second touch insulating layer 420.

The first conductive layer 430 may be disposed on the second touch insulating layer 420, and the third touch insulating layer 440 may be disposed on the first conductive layer 430. In an embodiment, the third touch insulating layer 440 may include an organic insulating material.

The second conductive layer 450 may be disposed on the third touch insulating layer 440. A touch electrode TE of the input detection layer 400 may have a structure in which the first conductive layer 430 and the second conductive layer 450 are connected to each other. Alternatively, the touch electrode TE may be disposed in any one of the first conductive layer 430 and the second conductive layer 450, and may include a metal line included in the corresponding conductive layer. The first conductive layer 430 and the second conductive layer 450 may each include at least one of Al, Cu, Ti, MO, and ITO, and may have a single-layer or multi-layer structure including the materials described above. For example, the first conductive layer 430 and the second conductive layer 450 may each have a three-layer structure of Ti/Al/Ti.

In an embodiment, the planarization layer 460 may cover the second conductive layer 450. The planarization layer 460 may include an organic insulating material.

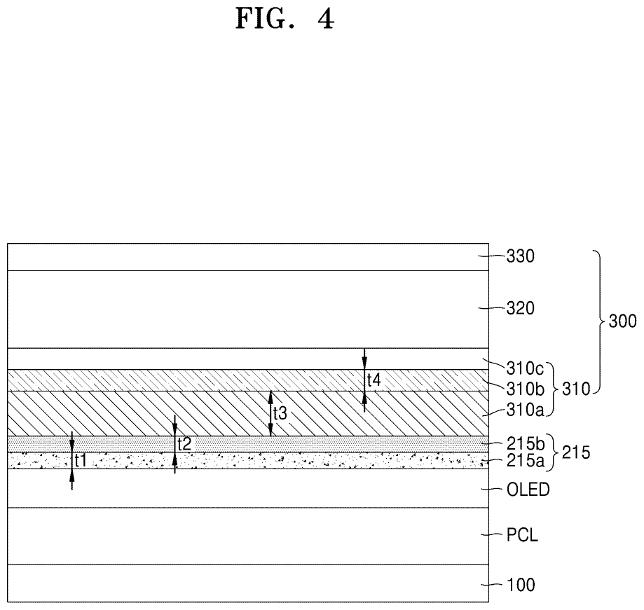

FIGS. 4 to 7 are schematic cross-sectional views of a portion of the display panel 10 according to some embodiments.

Referring to FIG. 4, a subpixel circuit layer PCL including the thin-film transistor TFT (refer to FIG. 3) and the storage capacitor Cst (refer to FIG. 3) may be disposed on the substrate 100. The organic light-emitting diode OLED may be disposed on the subpixel circuit layer PCL. The capping layer 215 may be disposed on the organic light-emitting diode OLED and the first inorganic encapsulation layer 310 may be disposed on the capping layer 215.

The capping layer 215 may include a first capping layer 215a and a second capping layer 215b disposed on the first capping layer 215a. The first capping layer 215a may have a first refractive index and the second capping layer 215b may have a second refractive index. The first refractive index of the first capping layer 215a may be greater than the second refractive index of the second capping layer 215b.

The first capping layer 215a may include IZO, TiO₂, SiNₓ, or other organic materials. However, the disclosure is not limited thereto. The second capping layer 215b may include SiON, silicon oxide (SiOx), LiF, or other organic materials. However, the disclosure is not limited thereto.

The first inorganic encapsulation layer 310 disposed on the capping layer 215 may include a first-1 inorganic encapsulation layer 310a, a first-2 inorganic encapsulation layer 310b, and a first-3 inorganic encapsulation layer 310c. The first-2 inorganic encapsulation layer 310b may be disposed on the first-1 inorganic encapsulation layer 310a, and the first-3 inorganic encapsulation layer 310c may be disposed on the first-2 inorganic encapsulation layer 310b. The first-1 inorganic encapsulation layer 310a may have a third refractive index, the first-2 inorganic encapsulation layer 310b may have a fourth refractive index, and the first-3 inorganic encapsulation layer 310c may have a fifth refractive index. The third refractive index of the first-1 inorganic encapsulation layer 310a may be greater than the second refractive index of the second capping layer 215b disposed below the first-1 inorganic encapsulation layer 310a. The fourth refractive index of the first-2 inorganic encapsulation layer 310b may be less than the third refractive index of the first-1 inorganic encapsulation layer 310a disposed below the first-2 inorganic encapsulation layer 310b. The fifth refractive index of the first-3 inorganic encapsulation layer 310c may be less than the fourth refractive index of the first-2 inorganic encapsulation layer 310b. In other words, the third refractive index of the first-1 inorganic encapsulation layer 310a may be the greatest, the fifth refractive index of the first-3 inorganic encapsulation layer 310c may be the least, and the fourth refractive index of the first-2 inorganic encapsulation layer 310b may be between the third refractive index and the fifth refractive index.

Particularly, the third refractive index of the first-1 inorganic encapsulation layer 310a may be about 1.79 to about 1.99. The refractive index of the first-2 inorganic encapsulation layer 310b may be about 1.6 to about 1.8. The refractive index of the first-3 inorganic encapsulation layer 310c may be about 1.42 to about 1.62. The third refractive index of the first-1 inorganic encapsulation layer 310a may be greater than the first-3 inorganic encapsulation layer 310c and the first-2 inorganic encapsulation layer 310b, thereby obtaining encapsulation characteristics of the first inorganic encapsulation layer 310.

Light emitted from the emission layer 212b (refer to FIG. 3) may be reflected from each of an interface between the organic light-emitting diode OLED and the first capping layer 215a, an interface between the first capping layer 215a and the second capping layer 215b, and an interface between the second capping layer 215b and the first-1 inorganic encapsulation layer 310a. By increasing the reflectivity of light reflected at each interface, light emission of light emitted from the emission layer 212b may be improved. To increase the reflectivity at an interface between layers of light emitted from the emission layer 212b, the difference in the refractive index between layers is desirable to be great. The second refractive index of the second capping layer 215b may be less than the first refractive index of the first capping layer 215a disposed below the second capping layer 215b, and the third refractive index of the first-1 inorganic encapsulation layer 310a may be greater than the second refractive index of the second capping layer 215b, thereby increasing the difference in the refractive index between the interface between the organic light-emitting diode OLED and the first capping layer 215a, the interface between the first capping layer 215a and the second capping layer 215b, and the interface between the second capping layer 215b and the first-1 inorganic encapsulation layer 310a. Accordingly, the reflectivity at each interface of light emitted from the emission layer 212b may be improved, and thus, light emission and reliability of the display device 1 may be effectively improved.

On the other hand, optical characteristics of the display device 1 may be obtained when light emitted from the emission layer 212b has low reflectivity in the interface between the first-1 inorganic encapsulation layer 310a and the first-2 inorganic encapsulation layer 310b and the interface between the first-2 inorganic encapsulation layer 310b and the first-3 inorganic encapsulation layer 310c. The fourth refractive index of the first-2 inorganic encapsulation layer 310b may be less than the third refractive index of the first-1 inorganic encapsulation layer 310a and the fifth refractive index of the first-3 inorganic encapsulation layer 310c may be less than the fourth refractive index of the first-2 inorganic encapsulation layer 310b, thereby decreasing the difference of the refractive index between the interface between the first-1 inorganic encapsulation layer 310a and the first-2 inorganic encapsulation layer 310b and the interface between the first-2 inorganic encapsulation layer 310b and the first-3 inorganic encapsulation layer 310c. Accordingly, the reflectivity at each interface of light emitted from the emission layer 212b may be decreased, and thus, optical characteristics and reliability of the display device 1 may be obtained.

In an embodiment, a thickness t1 of the first capping layer 215a may be about 100 Å to about 2,000 Å. A thickness t2 of the second capping layer 215b may be about 100 Å to about 2,000 Å. A thickness t3 of the first-1 inorganic encapsulation layer 310a may be about 1,000 Å to about 30,000 Å. When the thicknesses t1 and t2 of the first capping layer 215a and the second capping layer 215b each are about 100 Å to about 2,000 Å and the thickness t3 of the first-1 inorganic encapsulation layer 310a is about 1,000 Å to about 30,000 Å, light emitted from the emission layer 212b and reflected from the each of the interface between the organic light-emitting diode OLED and the first capping layer 215a, the interface between the first capping layer 215a and the second capping layer 215b, and the interface between the second capping layer 215b and the first-1 inorganic encapsulation layer 310a may cause a resonance effect, thereby improving light emission and reliability of the display device 1. As used herein, the thickness is measured in thickness direction (z direction).

In addition, the third refractive index of the first-1 inorganic encapsulation layer 310a may be about 1.79 to about 1.99, which is a relatively high refractive index, and the thickness t3 of the first-1 inorganic encapsulation layer 310a may be relatively great, thereby obtaining encapsulation characteristics of the display panel 10.

A thickness t4 of the first-2 inorganic encapsulation layer 310b may be about 300 Å to about 1,500 Å. When the thickness t4 of the first-2 inorganic encapsulation layer 310b is about 300 Å to about 1,500 Å, the reflectivity of light emitted from the emission layer 212b and reflected from the interface between the first-1 inorganic encapsulation layer 310a and the first-2 inorganic encapsulation layer 310b may be decreased and optical characteristics and reliability of the display device 1 may be obtained.

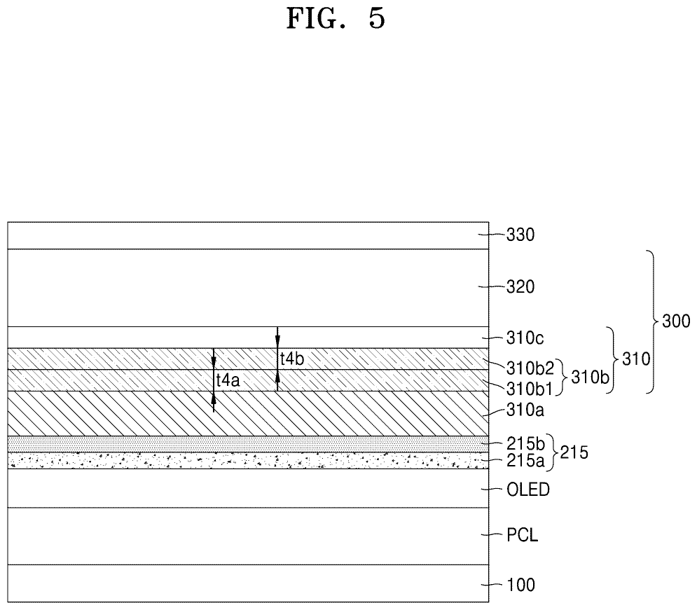

Referring to FIG. 5, in an embodiment, the first-2 inorganic encapsulation layer 310b may include a lower layer 310b1 and an upper layer 310b2. The remaining elements are the same as the embodiments shown in FIG. 4. The first-2 inorganic encapsulation layer 310b may be provided as two layers, thereby decreasing the reflectivity of light emitted from the emission layer 212b and reflected from the interfaces of the first-2 inorganic encapsulation layers 310b. Accordingly, optical characteristics and reliability of the display device 1 may be obtained.

Particularly, the refractive index of the lower layer 310b1 of the first-2 inorganic encapsulation layer 310b may be about 1.67 to about 1.87, and the thickness t4a thereof may be about 300 Å to about 1,500 Å. Particularly, the refractive index of the upper layer 310b2 of the first-2 inorganic encapsulation layer 310b may be about 1.52 to about 1.72, and a thickness t4b thereof may be about 300 Å to about 1,500 Å.

Referring to FIG. 6, unlike the embodiment shown in FIG. 4, the capping layer 215 may include the first capping layer 215a, the second capping layer 215b, and a third capping layer 215c. The third capping layer 215c may be disposed under the first capping layer 215a. In other words, the first capping layer 215a may be arranged between the second capping layer 215b and the third capping layer 215c.

In an embodiment, the first capping layer 215a may have a first refractive index. The second capping layer 215b disposed on the first capping layer 215a may have a second refractive index less than the first refractive index. The third capping layer 215c may have a sixth refractive index less than the first refractive index. In other words, the first refractive index of the first capping layer 215a may be relatively greater than the second refractive index of the second capping layer 215b and the sixth refractive index of the third capping layer 215c.

The second capping layer 215b and the third capping layer 215c may include SION, SiOx, LiF, or other organic materials. However, the disclosure is not limited thereto. The first capping layer 215a may include IZO, TiO₂, SiNₓ, or other organic materials. However, the disclosure is not limited thereto.

By providing the capping layer 215 as three layers with different refractive indices from each other and the difference between the refractive indices of the layers to be great, light emitted from the emission layer 212b may be reflected from the interface between the first capping layer 215a and the third capping layer 215c, in addition to the interface between the organic light-emitting diode OLED and the third capping layer 215c and the interface between the first capping layer 215a and the second capping layer 215b, thereby improving light emission and reliability of the display device 1.

A thickness t5 of the first capping layer 215a, a thickness t6 of the second capping layer 215b, and a thickness t7 of the third capping layer 215c may each be about 100 Å to about 2,000 Å. When the thickness t5 of the first capping layer 215a, the thickness t6 of the second capping layer 215b, and the thickness t7 of the third capping layer 215c are each about 100 Å to about 2,000 Å, light emitted from the emission layer 212b and reflected from the interface between the organic light-emitting diode OLED and the third capping layer 215c, the interface between the first capping layer 215a and the third capping layer 215c, the interface between the second capping layer 215b and the first capping layer 215a, and the interface between the second capping layer 215b and the first-1 inorganic encapsulation layer 310a may cause a resonance effect, and light emission and reliability of the display device 1 may be effectively improved.

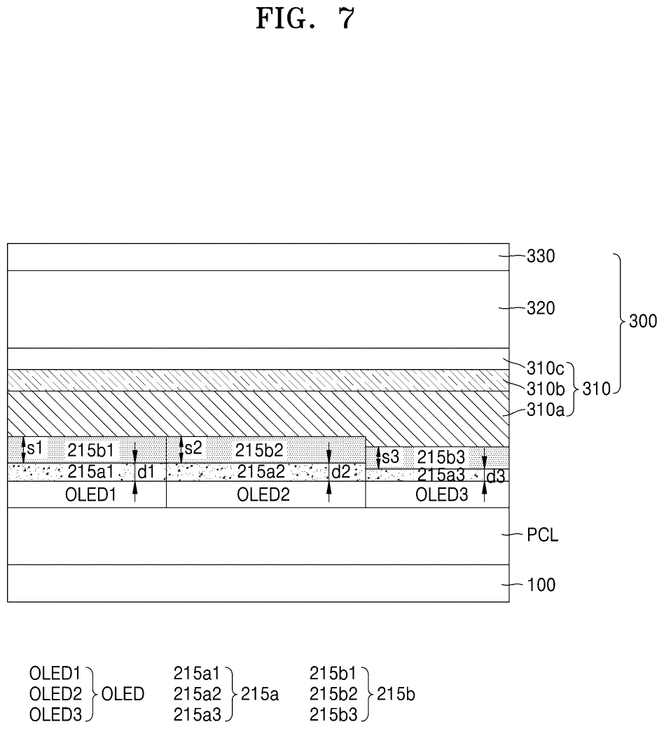

Referring to FIG. 7, the organic light-emitting diode OLED may include a first organic light-emitting diode OLED1, a second organic light-emitting diode OLED2, and a third organic light-emitting diode OLED3. The first organic light-emitting diode OLED1, the second organic light-emitting diode OLED2, and the third organic light-emitting diode OLED3 may emit light of different colors. For example, the first organic light-emitting diode OLED1 may emit red light, the second organic light-emitting diode OLED2 may emit green light, and the third organic light-emitting diode OLED3 may emit blue light.

A first-1 capping layer 215a1 and a second-1 capping layer 215b1 may be disposed on the first organic light-emitting diode OLED1. A first-2 capping layer 215a2 and a second-2 capping layer 215b2 may be disposed on the second organic light-emitting diode OLED2. A third-1 capping layer 215a3 and a third-2 capping layer 215b3 may be disposed on the third organic light-emitting diode OLED3.

The refractive index of the first-2 capping layer 215a2 may be less than the refractive index of the first-1 capping layer 215a1. The refractive index of the first-2 capping layer 215b1 may be less than the refractive index of the second-1 capping layer 215b1. The refractive index of the third-2 capping layer 215b3 may be greater than the refractive index of the third-1 capping layer 215a3. The refractive index of the first-1 inorganic encapsulation layer 310a may be greater than the refractive index of the second-1 capping layer 215b1, the second-2 capping layer 215b2, and the second-3 capping layer 215b3. The difference between the refractive indices of the first capping layer 215a, the second capping layer 215b, and the first-1 inorganic encapsulation layer 310a may be great, thereby increasing the difference between the refractive index at the interface between the organic light-emitting diode OLED and the first capping layer 215a, the interface between the first capping layer 215a and the second capping layer 215b, and the interface between the second capping layer 215b and the first-1 inorganic encapsulation layer 310a. Accordingly, the reflectivity at each interface of light emitted from the emission layer 212b may be improved and, as a result, light emission and reliability of the display device 1 may be effectively improved.

A thickness d1 of the first-1 capping layer 215a1, a thickness d2 of the first-2 capping layer 215a2, and a thickness d3 of a first-3 capping layer 215a3 may each be about 100 Å to about 2,000 Å. A thickness s1 of the second-1 capping layer 215b1, a thickness s2 of the second-2 capping layer 215b2, and a thickness s3 of the second-3 capping layer 215b3 may each be about 100 Å to about 2,000 Å. A thickness of the first-1 inorganic encapsulation layer 310a may be about 1,000 Å to about 30,000 Å. When the thickness d1 of the first-1 capping layer 215a1, the thickness d2 of the first-2 capping layer 215a2, the thickness d3 of the first-3 capping layer 215a3, the thickness s1 of the second-1 capping layer 215b1, the thickness s2 of the second-2 capping layer 215b2, and the thickness s3 of the second-3 capping layer 215b3 are each about 100 Å to about 2,000 Å and the thickness of the first-1 inorganic encapsulation layer 310a is about 1,000 Å to about 30,000 Å, light emitted from the emission layer 212b and reflected from the interface between the organic light-emitting diode OLED and the first capping layer 215a, the interface between the first capping layer 215a and the second capping layer 215b, and the interface between the second capping layer 215b and the first-1 inorganic encapsulation layer 310a may cause a resonance effect, and light emission and reliability of the display device 1 may be effectively improved.

In an embodiment, the thickness d1 of the first-1 capping layer 215a1 may be different from the thickness d3 of the first-3 capping layer 215a3. The thickness d1 of the first-1 capping layer 215a1 and the thickness d2 of the first-2 capping layer 215 may be equal to or different from each other. The thickness d1 of the first-1 capping layer 215a1 and the thickness d3 of the first-3 capping layer 215a3 may be different from each other, thereby decreasing a white angle dependency (“WAD”) of the display device 1.

In an embodiment, the thickness s1 of the second-1 capping layer 215b1 may be different from the thickness s3 of the second-3 capping layer 215b3. The thickness s1 of the second-1 capping layer 215b1 and the thickness s2 of the second-2 capping layer 215b2 may be equal to or different from each other. The thickness s1 of the second-1 capping layer 215b1 and the thickness s3 of the second-3 capping layer 215b3 may be different from each other, thereby decreasing the WAD of the display device 1.

In case of a micro patterned organic light-emitting diode (“MPO”), since the organic light-emitting diodes OLED emitting red, green, and blue light, respectively, are formed, the thicknesses of the first-1 capping layer 215a1, the first-2 capping layer 215a2, and the first-3 capping layer 215a3 may be different from each other or the thicknesses of the second-1 capping layer 215b1, the second-2 capping layer 215b2, and the second-3 capping layer 215be may be different from each other.

The refractive index of the first-1 inorganic encapsulation layer 310a may be greater than the refractive index of the second-1 capping layer 215b1, the second-2 capping layer 215b2, and the second-3 capping layer 215b3. The refractive index of the first-1 inorganic encapsulation layer 310a may be about 1.79 to about 1.99. In addition, a thickness of the first-1 inorganic encapsulation layer 310a may be about 1,000 Å to about 30,000 Å. The first-1 inorganic encapsulation layer 310a having a relatively high refractive index may be relatively thick, thereby obtaining encapsulation characteristics of the display panel 10.

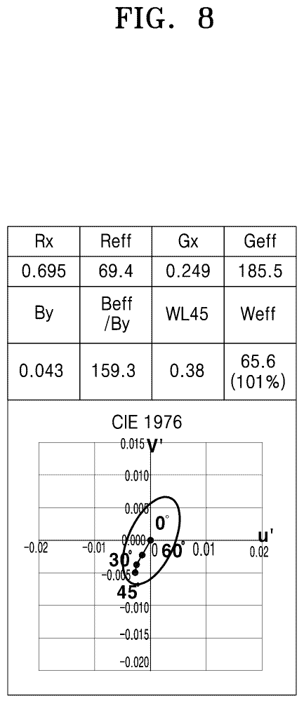

FIGS. 8 to 10 schematically show results of a simulation of light emission and WAD trajectory, according to an embodiment.

Referring to FIG. 8, in the embodiment shown in FIG. 4, when the thickness t1 of the first capping layer 215a is about 800 Å, the thickness t2 of the second capping layer 215b is about 11,000 Å, the thickness t3 of the first-1 inorganic encapsulation layer 310a is about 15,900 Å, and the thickness t4 of the first-2 inorganic encapsulation layer 310b is about 650 Å, the light emission of the display device 1 may be about 101% with respect to the structures being manufactured in the related art, and it can be seen that the WAD of the display device 1 is subtle.

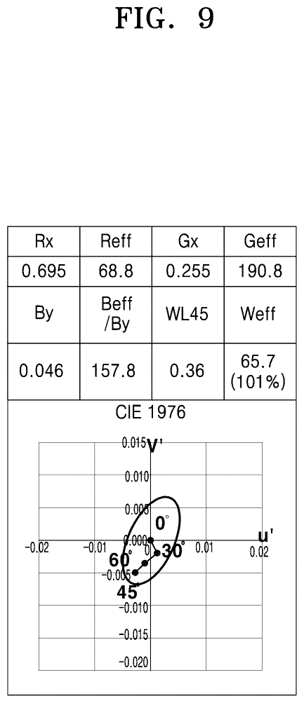

Referring to FIG. 9, in the embodiment shown in FIG. 6, when the thickness t5 of the third capping layer 215c is about 100 Å, the thickness t6 of the first capping layer 215a is about 750 Å, the thickness t7 of the second capping layer 215b is about 10,000 Å, the thickness of the first-1 inorganic encapsulation layer 310a is about 11,900 Å, and the thickness of the first-2 inorganic encapsulation layer 310b is about 650 Å, light emission of the display device 1 may be about 101% and it can be seen that the WAD of the display device 1 is subtle.

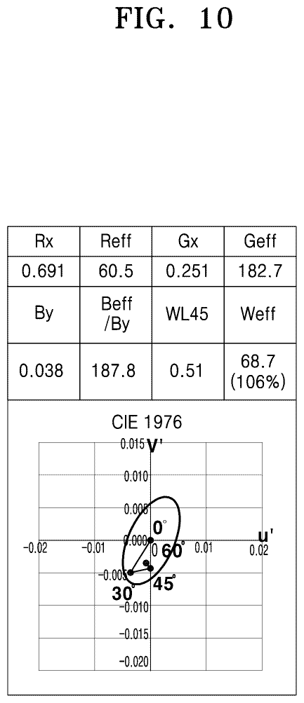

Referring to FIG. 10, in an embodiment shown in FIG. 7, when the thickness d1 of the first-1 capping layer 215a1 and the thickness d2 of the first-2 capping layer 215a2 are each about 650 Å, the thickness d3 of the first-3 capping layer 215a3 is about 450 Å, the thickness s1 of the second-1 capping layer 215b1 and the thickness s2 of the second-2capping layer 215b2 are each about 1,100 Å, the thickness s3 of the second-3 capping layer 215b3 is about 600 Å, the thickness of the first-1 inorganic encapsulation layer 310a is about 15,900 Å, and the thickness of the first-2 inorganic encapsulation layer 310b is about 650 Å, it can be seen that light emission of the display device 1 is about 106% and the WAD of the display device 1 is subtle.

In an embodiment, by providing the capping layer 215 as two or three layers having different refractive indices from each other, light emitted from the emission layer 212b may be reflected from the interfaces of the capping layer 215 at a high rate, thereby improving light emission of the display device 1, and, by providing the thickness of the capping layer 215 at about 100 Å to about 2,000 Å, the resonance effect of light reflected from the interfaces may be increased, or, by varying the thickness of the capping layer 215 between the organic light-emitting diodes OLED emitting different colors of light, the WAD of the display device 1 may be decreased, thereby effectively improving the reliability and quality of the display device.

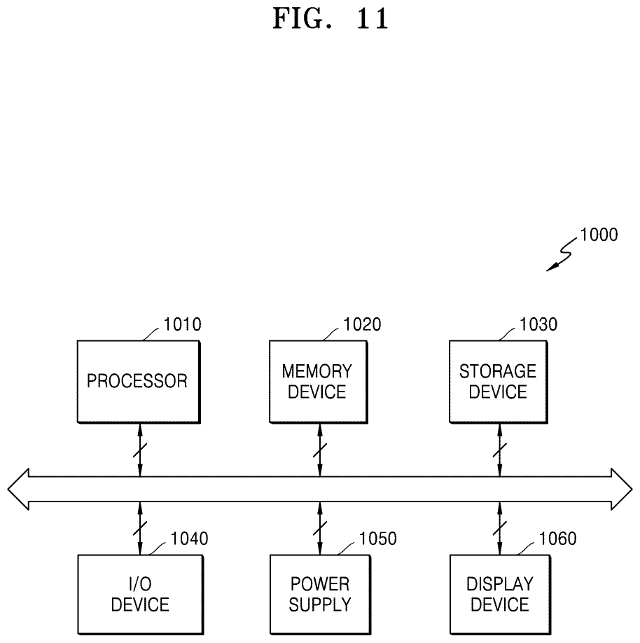

FIG. 11 is a block diagram illustrating an electronic device according to an embodiment.

Referring to FIG. 11, in an embodiment, an electronic device 1000 may include a processor 1010, a memory device 1020, a storage device 1030, an input/output (“I/O”) device 1040, a power supply 1050, and a display device 1060. Here, the display device 1060 may correspond to the display device 1 of FIG. 1. The electronic device 1000 may further include a plurality of ports for communicating with a video card, a sound card, a memory card, a universal serial bus (“USB”) device, or the like. In an embodiment, the electronic device 1000 may be implemented as a television. In another embodiment, the electronic device 1000 may be implemented as a smart phone. However, embodiments are not limited thereto, in another embodiment, the electronic device 1000 may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The processor 1010 may perform various computing functions. In an embodiment, the processor 1010 may be a microprocessor, a central processing unit (“CPU”), an application processor (“AP”), or the like. The processor 1010 may be coupled to other components via an address bus, a control bus, a data bus, or the like. In an embodiment, the processor 1010 may be coupled to an extended bus such as a peripheral component interconnection (“PCI”) bus.

The memory device 1020 may store data for operations of the electronic device 1000. In an embodiment, the memory device 1020 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 1030 may include a solid state drive (“SSD”) device, a hard disk drive (“HDD”) device, a CD-ROM device, or the like. In an embodiment, the I/O device 1040 may include an input device such as a keyboard, a keypad, a mouse device, a touchpad, a touch-screen, or the like, and an output device such as a printer, a speaker, or the like.

The power supply 1050 may provide power for operations of the electronic device 1000. The power supply 1050 may provide power to the display device 1060. The display device 1060 may be coupled to other components via the buses or other communication links. In an embodiment, the display device 1060 may be included in the I/O device 1040.

According to the embodiments described above, the display device with improved reliability and quality may be implemented. However, the scope of the disclosure is not limited by these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display device comprising:
a substrate;
a first organic light-emitting diode disposed on the substrate;
a first capping layer disposed on the first organic light-emitting diode and having a first refractive index;
a second capping layer disposed on the first capping layer and having a second refractive index less than the first refractive index; and
a first-1 inorganic encapsulation layer disposed on the second capping layer and having a third refractive index greater than the second refractive index.

2. The display device of claim 1, wherein the third refractive index of the first-1 inorganic encapsulation layer is about 1.79 to about 1.99.

3. The display device of claim 1, wherein a thickness of the first capping layer is about 100 angstroms (Å) to about 2,000 Å.

4. The display device of claim 1, wherein a thickness of the second capping layer is about 100 Å to about 2,000 Å.

5. The display device of claim 1, wherein a thickness of the first-1 inorganic encapsulation layer is about 1,000 Å to about 30,000 Å.

6. The display device of claim 1, further comprising a first-2 inorganic encapsulation layer disposed on the first-1 inorganic encapsulation layer and having a fourth refractive index less than the third refractive index.

7. The display device of claim 6, wherein the fourth refractive index of the first-2 inorganic encapsulation layer is about 1.6 to about 1.8.

8. The display device of claim 6, wherein a thickness of the first-2 inorganic encapsulation layer is about 300 Å to about 1,500 Å.

9. The display device of claim 6, wherein
the first-2 inorganic encapsulation layer comprises a lower layer and an upper layer,
a refractive index of the lower layer is about 1.67 to about 1.87, and
a refractive index of the upper layer is about 1.52 to about 1.72.

10. The display device of claim 9, wherein a thickness of each of the lower layer and the upper layer is about 300 Å to about 1,500 Å.

11. The display device of claim 6, further comprising a first-3 inorganic encapsulation layer disposed on the first-2 inorganic encapsulation layer and having a fifth refractive index less than the fourth refractive index.

12. The display device of claim 1, further comprising a third capping layer disposed under the first capping layer and having a sixth refractive index less than the second refractive index.

13. The display device of claim 12, wherein a thickness of the third capping layer is about 100 Å to about 2,000 Å.

14. An electronic device comprising:
a display device; and
a power supply configured to provide power to the display device,
wherein the display device comprises:
a substrate;
a first organic light-emitting diode, a second organic light-emitting diode, and a third organic light-emitting diode disposed on the substrate;
a first-1 capping layer disposed on the first organic light-emitting diode;
a first-2 capping layer disposed on the second organic light-emitting diode;
a first-3 capping layer disposed on the third organic light-emitting diode;
a second-1 capping layer disposed on the first-1 capping layer and having a refractive index less than a refractive index of the first-1 capping layer;
a second-2 capping layer disposed on the first-2 capping layer and having a refractive index less than a refractive index of the first-2 capping layer; and
a second-3 capping layer disposed on the first-3 capping layer and having a refractive index less than a refractive index of the first-3 capping layer,
wherein a thickness of the first-1 capping layer and a thickness of the first-3 capping layer are different from each other.

15. The electronic device of claim 14, wherein the first organic light-emitting diode, the second organic light-emitting diode, and the third organic light-emitting diode emit light of different colors from each other.

16. The electronic device of claim 14, wherein a thickness of the second-1 capping layer and a thickness of the second-3 capping layer are different from each other.

17. The electronic device of claim 14, wherein a thickness of each of the first-1 capping layer, the first-2 capping layer, the first-3 capping layer, the second-1 capping layer, the second-2 capping layer, and the second-3 capping layer is about 100 Å to about 2,000 Å.

18. The electronic device of claim 14, further comprising a first-1 inorganic encapsulation layer disposed on the second-1 capping layer, the second-2 capping layer, and the second-3 capping layer and having a refractive index greater than a refractive index of each of the second-1 capping layer, the second-2 capping layer, and the second-3 capping layer.

19. The electronic device of claim 18, wherein a refractive index of the first-1 inorganic encapsulation layer is about 1.79 to about 1.99.

20. The electronic device of claim 18, wherein a thickness of the first-1 inorganic encapsulation layer is about 1,000 Å to about 30,000 Å.
